(19) United States
(12) Patent Application Publication
(10) Pub. No.: US 2013/0000964 A1
(43) Pub. Date: Jan. 3, 2013

(54) ANISOTROPIC CONDUCTIVE MATERIAL AND CONNECTION STRUCTURE

(76) Inventors: Hiroshi Kobayashi, Mishima-gun (JP); Akihiko Tateno, Mishima-gun (JP); Hideaki Ishizawa, Mishima-gun (JP); Satoshi Saitou, Mishima-gun (JP)

(21) Appl. No.: 13/634,225

(22) PCT Filed: Apr. 19, 2011
(86) PCT No.: PCT/JP2011/059590

§ 371 Date: Sep. 11, 2012

(30) Foreign Application Priority Data
Apr. 22, 2010 (JP) 2010-099125

(51) Int. Cl. B23K 35/14; H05K 1/09

(52) U.S. Cl. 174/257; 228/56.3

(57) ABSTRACT

The present invention provides an anisotropic conductive material that facilitates connection between electrodes to enhance the conduction reliability when used for connecting the electrodes, and a connection structure produced from the anisotropic conductive material. The present invention is an anisotropic conductive material comprising: conductive particles (1) each including a resin particle (2) and a conductive layer (3) coating the surface (2a) of the resin particle (2); and a binder resin; wherein at least an exterior surface layer of the conductive layer is a solder layer (5). The present invention is a connection structure comprising: a first connection target member; a second connection target member; and a connection part connecting the first connection target member and the second connection target member, wherein the connection part is formed of the anisotropic conductive material.

### TECHNICAL FIELD

The present invention relates to an anisotropic conductive material comprising conductive particles each with a solder layer. More specifically, the present invention relates to an anisotropic conductive material used for electrical connection between electrodes, for example, and a connection structure produced from the anisotropic conductive material.

### BACKGROUND ART

Conductive particles are used for connections between an IC chip and a flexible printed circuit board, between liquid crystal driving IC chips, and between an IC chip and a circuit board having ITO electrodes. For example, after placed between an electrode of an IC chip and an electrode of a circuit board, conductive particles are heated and pressurized to contact with the electrode, so that the electrodes are electrically connected to each other.

The conductive particles are also used as an anisotropic conductive material in the form of particles dispersed in a binder resin.

As an example of the conductive particles, Patent Document 1 discloses conductive particles each comprising a base particle that is formed of nickel or glass and a solder layer coating the surface of the base particle. The conductive particles are used as an anisotropic conductive material in the form of a mixture with a polymer matrix.

Patent Document 2 discloses conductive particles each comprising a resin particle, a nickel-plated layer coating the surface of the resin particle, and a solder layer coating the surface of the nickel-plated layer.

### CITATION LIST

Patent Document 1: Patent Publication No. 2769491
Patent Document 2: JP-A 9-306231

### SUMMARY OF INVENTION

### Problems to be Solved by the Invention

In the conductive particles of Patent Document 1, since base particles are formed of glass or nickel, the conductive particles may settle out in the anisotropic conductive material. Accordingly, the anisotropic conductive material may not be applied uniformly in establishment of conductive connection to cause a case where conductive particles are not positioned between the upper and lower electrodes. Moreover, agglomerated conductive particles may cause short circuits between the electrodes adjacent to each other in the lateral direction.

Here, Patent Document 1 only discloses that the base particles of the conductive particles are formed of glass or nickel. More specifically, Patent Document 1 only discloses that the base particles are formed of a ferromagnetic metal such as nickel.

The conductive particles disclosed in Patent Document 2 are not dispersed in a binder resin. Since the conductive particles have a large particle size, the conductive particles are not favorably used in the form of an anisotropic conductive material comprising the conductive particles dispersed in a binder resin. In examples in Patent Document 2, the surfaces of the resin particles having a particle size of 650 μm are each coated with a conductive layer to provide conductive particles having a particle size of hundreds of micrometers. The conductive particles are not used as an anisotropic conductive material in which the conductive particles are mixed with a binder resin.

In Patent Document 2, a method of connecting electrodes of connection target members by conductive particles comprises the step of placing one conductive particle on one electrode, placing another electrode on the conductive particle, and heating them. A solder layer is molten by heating to join the electrodes. However, such a process of placing a conductive particle on an electrode is complicated. In addition, no resin layer is present between the connection target members, lowering the connection reliability.

The present invention aims to provide an anisotropic conductive material that facilitates connection between electrodes to enhance the conduction reliability when used for connecting the electrodes. The present invention also aims to provide a connection structure produced from the anisotropic conductive material.

A limitative aim of the present invention is to provide an anisotropic conductive material which hardly allows conductive particles to settle out so that the dispersibility of the conductive particles is improved. Another limitative aim of the present invention is to provide a connection structure produced from the anisotropic conductive material.

### Means for Solving the Problems

According to a broad aspect of the present invention, the present invention provides an anisotropic conductive material comprising: conductive particles each including a resin particle and a conductive layer coating the surface of the resin particle; and a binder resin; wherein at least an exterior surface layer of the conductive layer is a solder layer.

According to a specific aspect of the anisotropic conductive material according to the present invention, a difference in specific gravity is not more than 6.0 between the conductive particles and the binder resin.

According to another specific aspect of the anisotropic conductive material according to the present invention, the conductive particles have a specific gravity of 1.0 to 7.0 and the binder resin has a specific gravity of 0.8 to 2.0.

According to another specific aspect of the anisotropic conductive material according to the present invention, the conductive particles have an average particle size of 1 to 100 μm.

According to another specific aspect of the anisotropic conductive material according to the present invention, a flux is further contained.

According to another specific aspect of the anisotropic conductive material according to the present invention, the conductive particles each have a first conductive layer as a part of the conductive layer, in addition to the solder layer, between the resin particle and the solder layer.

According to another specific aspect of the anisotropic conductive material according to the present invention, the first conductive layer is a copper layer.

The amount of the conductive particles is preferably 1 to 50 wt % in 100 wt % of the anisotropic conductive material according to the present invention.

According to another specific aspect of the anisotropic conductive material according to the present invention, the anisotropic conductive material is in a liquid form with a viscosity of 1 to 300 Pa·s at 25° C. and 5 rpm.

According to another specific aspect of the anisotropic conductive material according to the present invention, the anisotropic conductive material is in a liquid form with a viscosity ratio of the viscosity at 25° C. and 0.5 rpm to the viscosity at 25° C. and 5 rpm of 1.1 to 3.0.

The connection structure according to the present invention comprises: a first connection target member; a second connection target member; and a connection part connecting the first connection target member and the second connection target member, wherein the connection part is formed of the anisotropic conductive material according to the present invention.

According to a specific aspect of the connection structure according to the present invention, the first connection target member has a plurality of first electrodes and the second connection target member has a plurality of second electrodes, and the plurality of first electrodes and the plurality of second electrodes are electrically connected to each other via the conductive particles included in the anisotropic conductive material.

According to another specific aspect of the connection structure according to the present invention, the plurality of first electrodes adjacent to each other are positioned at an interval of not more than 200 μm and the plurality of second electrodes adjacent to each other are positioned at an interval of not more than 200 μm, and the conductive particles have an average particle size of not more than ¼ of the interval between the plurality of first electrodes adjacent to each other and not more than ¼ of the interval between the plurality of second electrodes adjacent to each other.

### Effect of the Invention

The anisotropic conductive material according to the present invention contains the conductive particles and the binder resin which are specifically determined, and therefore, the anisotropic conductive material according to the present invention easily connect electrodes when used for connecting the electrodes. In addition, the conductive particles each include a resin particle and a conductive layer coating the surface of the resin particle, and at least the exterior surface layer of the conductive layer is a solder layer. This enhances the conduction reliability.

### BRIEF DESCRIPTION OF DRAWINGS

FIG. 1 is a cross-sectional view showing a conductive particle contained in the anisotropic conductive material according to one embodiment of the present invention.

FIG. 2 is a cross-sectional view showing a modified example of the conductive particle.

FIG. 3 is a front cross-sectional view schematically showing a connection structure produced from the anisotropic conductive material according to one embodiment of the present invention.

FIG. 4 is a front cross-sectional view showing an enlarged jointed portion between a conductive particle and electrodes in the connection structure shown in FIG. 3.

### MODES FOR CARRYING OUT THE INVENTION

Hereinafter, the present invention is described in detail.

The anisotropic conductive material according to the present invention contains conductive particles and a binder resin. The conductive particles each have a resin particle and a conductive layer coating the surface of the resin particle. At least the exterior surface of the conductive layer in each conductive particle is a solder layer.

The anisotropic conductive material according to the present invention have the above configuration, and therefore, the anisotropic conductive material according to the present invention easily connect electrodes when used for connecting the electrodes. Specifically, conductive particles do not need to be placed on electrodes provided on a connection target member one by one, for example, and simple application of the anisotropic conductive material on a connection target member allows placement of conductive particles on electrodes. In addition, after formation of an anisotropic conductive material layer on the connection target member, electrical connection between electrodes are conducted by simple stack of another connection target member on the anisotropic conductive material layer in such a manner that the electrodes face one another. Accordingly, it is possible to improve the production efficiency of the connection structure in which electrodes of connection target members are connected. Moreover, a binder resin is also present between the connection target members in addition to the conductive particles, the connection target members are solidly bonded to each other so that the connection reliability is enhanced.

In addition, when used for connecting electrodes, the anisotropic conductive material according to the present invention enhances the conduction reliability. Since the exterior surface layer of the conductive layer in each conductive particle is a solder layer, the contact area between the solder layer and the electrode can be increased, for example, by heating and melting the solder layer. Accordingly, the anisotropic conductive material according to the present invention is capable of enhancing the conduction reliability more, compared to an anisotropic conductive material containing conductive particles in which the exterior surface layer of the conductive layer is a metal layer other than a solder layer such as a gold layer and a nickel layer.

Additionally, the base particles in the conductive particles are resin particles formed of resin, not particles formed of glass or metal such as nickel, and therefore, the flexibility of the conductive particles is improved. This suppresses damage to an electrode coming in contact with the conductive particles. Moreover, use of the conductive particles comprising resin particles enhances the impact resistance of a connection structure connected via the conductive particles, compared to the case of using conductive particles comprising particles formed of glass or metal such as nickel.

Settlement of the conductive particles in the anisotropic conductive material is remarkably suppressed in the case where a difference in specific gravity is not more than 6.0 between the conductive particles and the binder resin, and in the case where the conductive particles have a specific gravity of 1.0 to 7.0 and the binder resin has a specific gravity of 0.8 to 2.0. Accordingly, the anisotropic conductive material is uniformly applied to the connection target members, so that the conductive particles are more surely placed between the upper and lower electrodes. In addition, the electrodes adjacent to each other in the lateral direction, which are not to be connected to each other, are hardly connected by the agglomerated conductive particles, so that short circuits are suppressed between the adjacent electrodes. This enhances the conduction reliability between the electrodes.

(Conductive Particles)

FIG. 1 is a cross-sectional view showing a conductive particle contained in the anisotropic conductive material according to one embodiment of the present invention.

As illustrated in FIG. 1, a conductive particle 1 comprises a resin particle 2 and a conductive layer 3 coating the surface 2a of the resin particle 2. The conductive particle 1 is a coated particle comprising the resin particle 2 having the surface 2a coated with the conductive layer 3. Accordingly, the conductive particle 1 has the conductive layer 3 on a surface 1a.

The conductive layer 3 comprises a first conductive layer 4 coating the surface 2a of the resin particle 2 and a solder layer 5 (second conductive layer) coating a surface 4a of the first conductive layer 4. The exterior surface layer of the conductive layer 3 is the solder layer 5. Accordingly, the conductive particle 1 has the solder layer 5 as a part of the conductive layer 3. The conductive particle 1 also has the first conductive layer 4 between the resin particle 2 and the solder layer 5, as a part of the conductive layer 3 in addition to the solder layer 5.

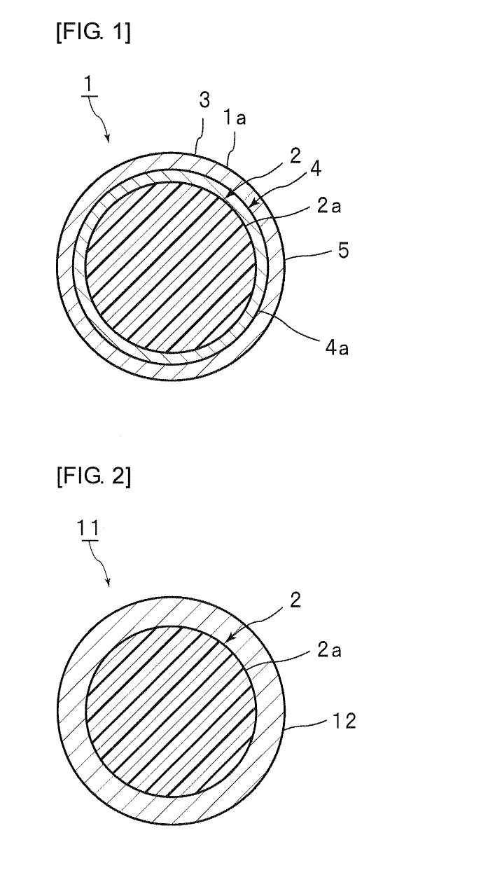

As mentioned above, the conductive layer 3 has a two-layer structure. As a modified example shown in FIG. 2, a conductive particle 11 may have a solder layer 12 as a mono-layer conductive layer. At least the exterior surface layer of the conductive layer in each conductive particle is needed to be a solder layer. From the standpoint of ease of production, the conductive particle 1 is more preferable than the conductive particle 11.

Methods are not particularly limited for forming the conductive layer 3 on the surface 2a of the resin particle 2 and for forming a solder layer on the surface 2a of the resin particle 2 or on the surface of the conductive layer. Exemplary methods for forming the conductive layer 3 and the solder layers 5 and 12 include electroless plating, electroplating, physical vapor deposition, and coating the surface of resin particles with a paste containing metallic powder and, optionally, a binder. In particular, electroless plating and electroplating are favorable. Exemplary methods of the physical vapor deposition include vacuum deposition, ion plating, and ion sputtering.

The method for forming the solder layers 5 and 12 is preferably electroplating because the solder layers are easily formed by that method. The solder layers 5 and 12 are preferably formed by electroplating.

From the standpoint of the productivity improvement, physical collision is also usable as the method for forming the solder layers 5 and 12. Exemplary methods of physical collision include coating using a Theta Composer (produced by TOKUJU CORPORATION).

The materials of the solder layer is not particularly limited as long as it is a filler metal having a liquidus temperature of not higher than 450° C. in accordance with JIS Z3001: Solvent terms. Exemplary compositions of the solder layer include a metallic composition containing zinc, gold, lead, copper, tin, bismuth, indium, and the like. Preferable among these is tin-indium alloy (eutectic at 117° C.) or tin-bismuth alloy (eutectic at 139° C.) as it is a low-melting and lead-free alloy. Namely, the solder layer is preferably free from lead, and is preferably a solder layer containing tin and indium or a solder layer containing tin and bismuth.

Conventional conductive particles each having a solder layer as the exterior surface layer of the conductive layer have a particle size of about hundreds of micrometers.

Attempts to obtain conductive particles having a particle size of tens of micrometers and each with a solder layer as the exterior surface layer of the conductive layer have failed because a uniform solder layer could not be formed. In contrast, in the case where dispersion conditions are optimized in electroless plating for forming a solder layer, a solder layer is uniformly formed on the surface of each resin particle or of the conductive layer even in the case where conductive particles having a particle size of tens of micrometers, in particular a particle size of 1 to 100 μm, are to be formed.

In the conductive layer 3, the first conductive layer 4 different from the solder layer is preferably formed of metal. The metal forming the first conductive layer different from the solder layer is not particularly limited. Examples thereof include gold, silver, copper, platinum, palladium, zinc, lead, aluminum, cobalt, indium, nickel, chromium, titanium, antimony, bismuth, germanium, cadmium, and alloys of these. Also, tin-doped indium oxide (ITO) is usable. Each of these metals may be used alone, or two or more of these may be used in combination.

The first conductive layer 4 is preferably a nickel, palladium, copper, or gold layer, more preferably a nickel or gold layer, and still more preferably a copper layer. The conductive particles preferably has a nickel, palladium, copper or gold layer, more preferably a nickel or gold layer, and still more preferably a copper layer. Use of the conductive particles each having such a preferable conductive layer for connecting the electrodes further lowers the connection resistance between the electrodes. Additionally, on the surface of such a preferable conductive layer, a solder layer is more easily formed. Here, the first conductive layer 4 may be a solder layer. The conductive particles may each have plural solder layers.

The solder layers 5 and 12 each preferably has a thickness of 5 to 40,000 nm. The lower limit of the thickness of the solder layers 5 and 12 is more preferably 10 nm, and still more preferably 20 nm. The upper limit thereof is more preferably 30,000 nm, still more preferably 20,000 nm, and particularly preferably 10,000 nm. The thickness of the solder layers 5 and 12 satisfying the lower limit allows sufficient improvement in the conductivity. The thickness of the conductive layer satisfying the upper limit allows the difference in the thermal expansion coefficient to be narrowed between the resin particles 2 and the solder layers 5 and 12, so that peeling of the solder layers 5 and 12 hardly occur.

In the case where the conductive layer has a multilayer structure, the total thickness of conductive layers (the thickness of the conductive layer 3; the total thickness of the first conductive layer 4 and the solder layer 5) is preferably 10 to 40,000 nm. In the case where the conductive layer has a multilayer structure, the upper limit of the total thickness of conductive layers is more preferably 30,000 nm, still more preferably 20,000 nm, and particularly preferably 10,000 nm. In the case where the conductive layer has a multilayer structure, the total thickness of conductive layers (the thickness of the conductive layer 3; the total thickness of the first conductive layer 4 and the solder layer 5) is more preferably 10 to 10,000 nm. In the case where the conductive layer has a multilayer structure, the lower limit of the total thickness of conductive layers is more preferably 20 nm, and particularly preferably 30 nm. The upper limit thereof is more preferably 80,000 nm, still more preferably 7,000 nm, particularly preferably 6,000 nm, and most preferably 5,000 nm.

Examples of the resin forming the resin particles 2 include polyolefin resin, acrylic resin, phenol resin, melamine resin, benzoguanamine resin, urea resin, epoxy resin, unsaturated polyester resin, saturated polyester resin, polyethyleneterephthalate, polysulfone, polyphenylene oxide, polyacetal, polyimide, polyamideimide, polyetheretherketone, and polyethersulfone. The resin forming the resin particles 2 is preferably a polymer in which at least one kind of polymerizable monomer having an ethylenically unsaturated group is polymerized, because the hardness of the resin particles 2 can be easily controlled within a favorable range.

The conductive particles 1 and 11 preferably have an average particle size of 1 to 100 μm. The lower limit of the average particle size of the conductive particles 1 and 11 is more preferably 1.5 μm and the upper limit thereof is more preferably 80 μm. The upper limit is still more preferably 50 μm and particularly preferably 40 μm. The average particle size of the conductive particles 1 and 11 satisfying the lower limit and the upper limit allows sufficient increase in the contact area between the electrodes and the conductive particles 1 and 11 and is less likely to cause formation of agglomerated conductive particles 1 and 11 during formation of the conductive layer. Moreover, the interval between electrodes connected via the conductive particles 1 and 11 is not too large and the conductive layer is less likely to be peeled from the surface 2a of each resin particle 2.

The average particle size of the conductive particles 1 and 11 is particularly preferably in a range of 1 to 100 μm because such a size is appropriate as conductive particles in an anisotropic conductive material and the interval between electrodes can be further narrowed.

The resin particles may be selected in accordance with the electrode size or the land diameter of a substrate to be used.

For more surely connecting the upper and lower electrodes and further suppressing short circuits between the electrodes adjacent to each other in the lateral direction, the average particle size C of the conductive particles and the average particle size A of the resin particles have a ratio (C/A) of more than 1.0 and preferably not more than 2.0. In the case where the first conductive layer is provided between the resin particles and the solder layer, the average particle size B of a conducive particle part other than the solder layer and the average particle size A of the resin particles have a ratio (B/A) of more than 1.0 and preferably not more than 1.5. Moreover, in the case where the first conductive layer is provided between the resin particles and the solder layer, the average particle size C of the conducive particles including the solder layer and the average particle size B of the conducive particle part other than the solder layer have a ratio (C/B) of more than 1.0 and preferably not more than 2.0. The ratio (B/A) within the above range or the ratio (C/B) within the above range allows the upper and lower electrodes to be more surely connected to each other and short circuits to be further suppressed between the electrodes adjacent to each other in the lateral direction.

Anisotropic conductive material for FOB and FOF applications:

The anisotropic conductive material according to the present invention is suitably used for connection between a flexible printed circuit board and a glass epoxy board (FOB (Film on Board)) or connection between flexible printed circuit boards (FOF (Film on Film)).

In FOB and FOF applications, L&S is commonly 100 to 500 μm, which indicates the size of a part (Line) where an electrode is present and a part (Space) where no electrode is present. The resin particles for FOB and FOF applications preferably have an average particle size of 10 to 100 μm. The average particle size of 10 μm or more allows the anisotropic conductive material placed between the electrodes and the connection part to be sufficiently thick, so that the adhesion force is further improved. The average particle size of not more than 100 μm further suppresses short circuits between the adjacent electrodes.

Anisotropic conductive material for flip chip application:

The anisotropic conductive material according to the present invention is suitably used for flip chip applications.

In flip chip applications, the land diameter is commonly 15 to 80 μm. The resin particles used in flip chip applications preferably have an average particle size of 1 to 15 μm. The average particle size of 1 μm or more allows the solder layer positioned on the surface of the resin particles to be sufficiently thick, so that the electrodes are more surely electrically connected to each other. The average particle size of 10 μm or less further suppresses short circuits between the adjacent electrodes.

Anisotropic conductive material for COF:

The anisotropic conductive material according to the present invention is suitably used for connection between a semiconductor chip and a flexible printed circuit board (COF (Chip on Film).

In COF applications, L&S is commonly 10 to 50 μm, which indicates the size of a part (Line) where an electrode is present and a part (Space) where no electrode is present. The resin particles used in COF applications preferably have an average particle size of 1 to 10 μm. The average particle size of 1 μm or more allows the solder layer positioned on the surface of the resin particles to be sufficiently thick, so that the electrodes are more surely electrically connected to each other. The average particle size of 10 μm or less further suppresses short circuits between the adjacent electrodes.

The “average particle size” of the resin particles 2 or the conductive particles 1 and 11 indicates a number average particle size. The average particle sizes of the resin particles 2 and of the conductive particles 1 and 11 are each obtained by observation of any 50 conductive particles using an electron microscope or optical microscope followed by calculation of the average value.

(Anisotropic Conductive Material)

The anisotropic conductive material according to the present invention contains the above-mentioned conductive particles and a binder resin. Namely, the conductive particles contained in the anisotropic conductive material according to the present invention each comprise a resin particle and a conductive layer coating the surface of the resin particle, and at least an exterior surface layer of the conductive layer is a solder layer. The anisotropic conductive material according to the present invention is preferably in a liquid form and is preferably an anisotropic conductive paste.

In the case where the anisotropic conductive material according to the present invention is in a liquid form, the viscosity η5 at 25° C. and 5 rpm is preferably 1 to 300 Pa·s. The viscosity of η0.5 (Pa·s) at 25° C. and 0.5 rpm and the viscosity η5 (Pa·s) at 25° C. and 5 rpm preferably have a viscosity ratio (η0.5/η5) of 1.1 to 3.0. The viscosity η5 and the viscosity ratio (η0.5/η5) within the above ranges allow further improvement in the spreadability of the anisotropic conductive material using a dispenser and the like. The viscosities η5 and η0.5 are determined using an S-type viscometer.

The binder resin is not particularly limited. For example, insulating resin is usable as the binder resin. Examples of the binder resin include vinyl resins, thermoplastic resins, curable resins, thermoplastic block copolymers, and elastomers. Each of these binder resins may be used alone or two or more of them may be used in combination.

Specific examples of the vinyl resins include vinyl acetate resin, acrylic resin, and styrene resin. Specific examples of the thermoplastic resins include polyolefine resin, ethylene-vinyl acetate copolymers, and polyamide resin. Specific examples of the curable resins include epoxy resin, urethane resin, polyimide resin, and unsaturated polyester resin. Here, the curable resins may be ambient-temperature curable resins, thermosetting resins, photocurable resins, or moisture curable resins. Specific examples of the thermoplastic block copolymers include styrene-butadiene-styrene block copolymers, styrene-isoprene-styrene block copolymers, hydrogenated styrene-butadiene-styrene block copolymers, and hydrogenated styrene-isoprene-styrene block copolymers. Specific examples of the elastomers include styrene-butadiene copolymer rubber and acrylonitrile-styrene block copolymer rubber.

The binder resin is preferably thermosetting resin. In such a case, heating for electrically connecting electrodes melts the solder layer of each conductive particle and at the same time cures the binder resin. Therefore, electrical connection between electrodes by the solder layer and bonding of the connection target members by the binder resin are concurrently conducted.

The binder resin is preferably epoxy resin. In such a case, the connection reliability of the connection structure is further enhanced. In the case of bonding connection target members having flexibility such as flexible boards, it is preferable to set the cured resin have a low elastic region for improving the peel strength. From this standpoint, the binder resin used in the anisotropic conductive material preferably has elasticity of 3000 MPa or less at 25° C. The elasticity not higher than the upper limit allows distribution of the stress at an edge portion upon application of a peel stress, so that the adhesion force is improved. The elasticity of the binder resin used in the anisotropic conductive material is more preferably 2500 MPa or less, and still more preferably 2000 MPa or less. For improvement in the peel strength, the binder resin used in the anisotropic conductive material preferably has a glass transition temperature (Tg) of not lower than 10° C. and not higher than 70° C.

The epoxy resin capable of setting the elasticity within the appropriate range is not particularly limited, and may be flexible epoxy resin. The flexible epoxy resin is preferably, for example, epoxy resin having an aliphatic polyether skeleton, and more preferably epoxy resin having an aliphatic polyether skeleton and a glycidyl ether group.

The aliphatic polyether skeleton is preferably alkylene glycol skeleton. Examples of the alkylene glycol skeleton include polypropylene glycol skeleton and polytetramethylene glycol skeleton. Examples of the epoxy resin having such a skeleton include polytetramethylene glycol diglycidyl ether, polypropylene glycol diglycidyl ether, polyethylene glycol diglycidyl ether, and polyhexamethylene glycol diglycidyl ether.

Commercial products of the flexible epoxy resin include Epogosey PT (produced by Yokkaichi Chemical Company, Limited), EX-841 (produced by Nagase ChemteX Corporation), YL7175-500 (produced by Mitsubishi Chemical Corporation), YL7175-1000 (produced by Mitsubishi Chemical Corporation), EP-4000S (produced by ADEKA CORPORATION), EP-4000L (produced by ADEKA CORPORATION), EP-4003S (produced by ADEKA CORPORATION), EP-4010S (produced by ADEKA CORPORATION), EXA-4850-150 (produced by DIC Corporation) and EXA-4850-1000 (produced by DIC Corporation).

The anisotropic conductive material according to the present invention preferably contains a curing agent for curing the binder resin.

The curing agent is not particularly limited. Examples of the curing agent include imidazole curing agents, amine curing agents, phenol curing agents, polythiol curing agents, and acid anhydride curing agents. Each of these curing agents may be used alone, or two or more of them may be used in combination.

In the case where the anisotropic conductive material is in a liquid form, it is desirably avoided that a liquid anisotropic conductive material is squeezed out upon bonding to be placed in an unwanted area. From this standpoint, it is sometimes advantageous to have the anisotropic conductive material subjected to, if needed, B-staging by photoirradiation or heat application. For example, blending with resin having a (meth)acryloyl group and a compound generating radicals by light or heat allows the anisotropic conductive material to be B-staged.

The anisotropic conductive material according to the present invention preferably further contains a flux. Use of the flux is less likely to cause formation of an oxide film on the surface of the solder layer, and moreover, efficiently removes an oxide film formed on the surface of the solder layer or the electrode.

The flux is not particularly limited, and ones generally used in solder bonding may be used. Examples thereof include zinc chloride, a mixture of zinc chloride and an inorganic halide, a mixture of zinc chloride and an inorganic acid, fused salt, phosphoric acid, phosphoric acid derivatives, organic halides, hydrazine, organic acids, and pine resin. Each of these fluxes may be used alone, or two or more of them may be used in combination.

Examples of the fused salt include ammonium chloride. Examples of the organic acids include lactic acid, citric acid, stearic acid, glutamic acid, and hydrazine. Examples of the pine resin include activated pine resin and deactivated pine resin. The flux is preferably pine resin. Use of the pine resin lowers the connection resistance between electrodes.

The pine resin is rosin mainly comprising abietic acid. The flux is preferably rosin, and more preferably abietic acid. Use of such a preferable flux further lowers the connection resistance between electrodes.

The flux may be dispersed in the binder resin, or adhered to the surface of the conductive particles.

The anisotropic conductive material according to the present invention may contain a basic organic compound for adjusting the activity of the flux. Examples of the basic organic compound include aniline hydrochloride and hydrazine hydrochloride.

Difference in the specific gravity is preferably not more than 6.0 between the conductive particles and the binder resin. In such a case, settlement of the conductive particles is suppressed during storage of the anisotropic conductive material. Accordingly, the anisotropic conductive material is applied uniformly to the connection target members, so that the conductive particles are more surely placed between the upper and lower electrodes. Moreover, short circuits, which may be caused by agglomerated conductive particles, are suppressed between the electrodes adjacent to each other in the lateral direction. In addition, the conduction reliability between the electrodes is enhanced.

Preferably, the conductive particles have a specific gravity of 1.0 to 7.0 and the binder resin has a specific gravity of 0.8 to 2.0. Also in this case, settlement of the conductive particles is suppressed during storage of the anisotropic conductive material. Accordingly, the conductive particles are more surely placed between the upper and lower electrodes. Moreover, short circuits, which may be caused by agglomerated conductive particles, are suppressed between the electrodes adjacent to each other in the lateral direction, so that the conduction reliability between electrodes is enhanced.

Particularly preferably, difference in the specific gravity is not more than 6.0 between the conductive particles and the binder resin, the conductive particles have a specific gravity of 1.0 to 7.0, and the binder resin has a specific gravity of 0.8 to 2.0.

From the standpoint of further suppressing settlement of the conductive particles during storage of the anisotropic conductive material, the amount of the binder resin is preferably 30 to 99.99 wt % in 100 wt % of the anisotropic conductive material. The lower limit of the amount of the binder resin is more preferably 50 wt %, and still more preferably 80 wt %. The upper limit thereof is more preferably 99 wt %. The amount of the binder resin satisfying the lower limit and the upper limit further suppresses settlement of the conductive particles and further enhances the connection reliability of the connection target members connected via the anisotropic conductive material.

In the case of using a curing agent, the amount of the curing agent is preferably 0.01 to 100 parts by weight for 100 parts by weight of the binder resin (curable component). The lower limit of the amount of the curing agent is more preferably 0.1 parts by weight. The upper limit thereof is more preferably 50 parts by weight, and still more preferably 20 parts by weight. The amount of the curing agent satisfying the lower limit and the upper limit allows the binder resin to be sufficiently cured and suppresses generation of residues derived from the curing agent after the curing.

In the case where the curing agent reacts equivalently, the functional group equivalent of the curing agent is preferably 30 equivalents or more and 110 equivalents or less for 100 curable functional group equivalents of the binder resin (curable component).

The amount of the conductive particles is preferably 1 to 50 wt % in 100 wt % of the anisotropic conductive material. The lower limit of the amount of the conductive particles is more preferably 2 wt %. The upper limit thereof is more preferably 45 wt %. The amount of the conductive particles satisfying the lower limit and the upper limit further suppresses settlement of the conductive particles and further enhances the conduction reliability between the electrodes.

The amount of the flux is preferably 0 to 30 wt % in 100 wt % of the anisotropic conductive material. The anisotropic conductive material may not contain the flux. The lower limit of the amount of the flux is more preferably 0.5 wt %. The upper limit thereof is more preferably 25 wt %. The amount of the flux satisfying the lower limit and the upper limit further suppresses formation of an oxide film on the surface of the solder layer, and allows more efficient removal of an oxide film formed on the surface of the solder layer or the electrode. Moreover, the amount of the flux not smaller than the lower limit allows more efficient exertion of the effect of the flux addition. The amount of the flux not larger than the upper limit further lowers moisture absorption by the cured product, so that the reliability of the connection structure is further enhanced.

The anisotropic conductive material according to the present invention may further contain various additives such as fillers, bulking agents, softners, plasticizers, polymerization catalysts, curing catalyst, colorants, antioxidants, heat stabilizers, light stabilizers, ultraviolet absorbers, lubricants, antistatic agents, and flame retardants.

Examples of the fillers include inorganic particles. The anisotropic conductive material according to the present invention preferably contains inorganic particles, especially, surface-treated inorganic particles. In such a case, the viscosity η0.5 and the viscosity ratio (η0.5/η5) are easily controlled to the preferable values mentioned above.

Examples of the surface-treated inorganic particles include DM-10, DM-30, MT-b, ZD-30ST, HM-20L, PM-20L, QS-40, and KS-20S (all produced by Tokuyama Corporation), R-972, RX-200, R202, R-976 (all produced by Degussa), silica surface-treated with a phenylsilane coupling agent and microparticulate silica treated with a phenylsilane coupling agent (produced by Admatechs), and UFP-80 (produced by DENKI KAGAKU KOGYO KABUSHIKI KAISHA).

From the standpoint of easily controlling the viscosity η0.5 and the viscosity ratio (η0.5/η5) to the preferable values mentioned above, the amount of the inorganic particles is preferably 1 part by weight or more and 10 parts by weight or less for 100 parts by weight of the binder resin.

A method for dispersing the conductive particles in the binder resin may be a conventionally known dispersion method and is not particularly limited. For example, after added to the binder resin, the conductive particles may be kneaded with a planetary mixer to be dispersed in the binder resin. Alternatively, after uniformly dispersed in water or an organic solvent using a homogenizer, the conductive particles are added to the binder resin and then kneaded with a planetary mixer to be dispersed in the binder resin. Moreover, the conductive particles may be added to the binder resin preliminary diluted with water or an organic solvent, and then kneaded with a planetary mixer to be dispersed in the binder resin.

The anisotropic conductive material according to the present invention can be used for an anisotropic conductive paste or an anisotropic conductive film. The anisotropic conductive paste may be an anisotropic conductive ink or an anisotropic conductive adhesive. Moreover, the anisotropic conductive film may be an anisotropic conductive sheet. In the case where the anisotropic conductive material of the present invention which contains conductive particles is used as a film-like adhesive such as an anisotropic conductive film, a film-like adhesive containing no conductive particles may be stacked on the film-like adhesive containing the conductive particles. However, as mentioned above, the anisotropic conductive material according to the present invention is preferably in a liquid form and is preferably an anisotropic conductive paste.

### (Connection Structure)

The anisotropic conductive material according to the present invention is used to connect connection target members to each other to provide a connection structure.

The connection structure preferably comprises a first connection target member, a second connection target member, and a connection part electrically connecting the first connection target member and the second connection target member, wherein the connection part is formed of the anisotropic conductive material according to the present invention.

Preferably, the first connection target member has a plurality of first electrodes, the second connection target member has a plurality of second electrodes, and the first electrodes and the second electrodes are electrically connected to each other via the conductive particles contained in the anisotropic conductive material.

Preferably, the plurality of first electrodes adjacent to each other are positioned at an interval of not more than 200 μm, the plurality of second electrodes adjacent to each other are positioned at an interval of not more than 200 μm, the conductive particles have an average particle size of not more than ¼ of the interval between the plurality of first electrodes adjacent to each other and not more than ¼ of the interval between the plurality of second electrodes adjacent to each other. In such a case, short circuits between the electrodes adjacent to each other in the lateral direction are still less likely to occur. The interval between the electrodes refers to the size of a part (space) where the electrode is not present.

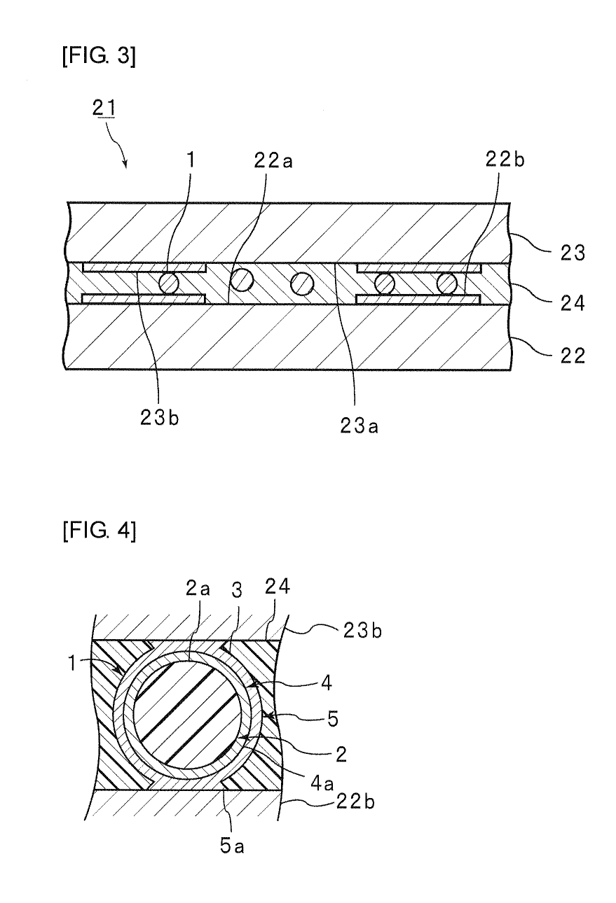

FIG. 3 is a front cross-sectional view schematically showing a connection structure produced from the anisotropic conductive material according to one embodiment of the present invention.

A connection structure 21 illustrated in FIG. 3 comprises a first connection target member 22, a second connection target member 23, and a connection part 24 connecting the first and second connection target members 22 and 23. The connection part 24 is formed of a cured anisotropic conductive material containing the conductive particles 1. In FIG. 3, the conductive particles 1 are abbreviated for illustration purposes.

The first connection target member 22 has a plurality of first electrodes 22b on a top surface 22a. The second connection target member 23 has a plurality of second electrodes 23b on an under surface 23a. The first electrodes 22b and the second electrodes 23b are electrically connected via a single or a plurality of conductive particles 1. Accordingly, the first and second connection target members 22 and 23 are electrically connected to each other via the conductive particles 1.

A method for producing the connection structure is not particularly limited. An exemplary method for producing the connection structure include the step of placing the anisotropic conductive material between the first connection target member and the second connection target member to obtain a stack, and heating and pressurizing the stack. Heating and pressurization melt the solder layer 5 of each conductive particle 1 so that the conductive particles 1 electrically connect the electrodes. Further, in the case where the binder resin is thermosetting resin, the binder resin is cured to bond the first and second connection target members 22 and 23 together.

The pressure applied in the pressurization is about 9.8×10⁴ to 4.9×10⁶ Pa. The heating temperature is about 120° C. to 220° C.

FIG. 4 is a front cross-sectional view showing an enlarged jointed portion between the conductive particle and the first and second electrodes 22b and 23b in the connection structure 21 shown in FIG. 3. As illustrated in FIG. 4, in the connection structure 21, the stack is heated and pressurized so that the solder layer 5 of each conductive particle 1 is molten, and a molten solder layer part 5a makes the first and second electrodes 22b and 23b sufficiently in contact with each other. Namely, use of the conductive particles each having the solder layer 5 as a surface layer increases the contact area between the conductive particles 1 and the electrodes 22b and 23b, compared to the case of using conductive particles in which the surface layer of the conductive layer is formed of a metal such as nickel, gold, and copper. Because of this, the conduction reliability of the connection structure 21 is enhanced. It is to be noted that, commonly, heating gradually deactivates the flux.

Specific examples of the connection target members include electronic components such as semiconductor chips, capacitors, diodes, and circuit boards (e.g. flexible printed circuit board, glass board). The anisotropic conductive material is preferably an anisotropic conductive material for connecting electronic components. The anisotropic conductive material is preferably in a liquid form and applied in a liquid state to a top surface of the connection target member.

Examples of the electrode provided on the connection target members include metal electrodes such as gold, nickel, tin, aluminum, copper, molybdenum, and tungsten electrodes. In the case that the connection target members are flexible printed circuit boards, the electrodes are preferably gold, nickel, tin, or copper electrodes. In the case that the connection target members are glass boards, the electrodes are preferably aluminum, copper, molybdenum, or tungsten electrodes. In the case where the electrodes are aluminum electrodes, the electrodes may be electrodes formed only of aluminum or electrodes in which an aluminum layer is stacked on the surface of a metal oxide layer. Examples of the metal oxides include trivalent metal element-doped indium oxide and trivalent metal element-doped zinc oxide. Examples of the trivalent metal element include Sn, Al, and Ga.

Hereinafter, the present invention is specifically described referring to examples and comparative examples. The present invention is, however, not limited to those examples.

### Example 1

### (1) Preparation of Conductive Particles

Divinyl benzene resin particles (produced by SEKISUI CHEMICAL CO., LTD., Micropearl SP-220) having an average particle size of 20 μm were subjected to electroless nickel plating so that a base nickel plated layer having a thickness of 0.1 μm was formed on the surface of each resin particle. Next, the resin particles each having the base nickel plated layer formed thereon were subjected to electro-copper plating so that a copper layer having a thickness of 1 μm was formed. Then, the resulting particles were subjected to electroplating using an electroplating solution containing tin and bismuth so that a solder layer having a thickness of 1 μm was formed on each surface. Thus, conductive particles A were prepared in which a copper layer having a thickness of 1 μm was formed on each surface of the resin particles and a solder layer (tin:bismuth=43:57 (wt %)) having a thickness of 1 μm was formed on the surface of the copper layer.

### (2) Preparation of Anisotropic Conductive Material

TEPIC-PAS B22 (100 parts by weight, produced by NISSAN CHEMICAL INDUSTRIES, LTD., specific gravity of 1.2) as a binder resin, TEP-2E4MZ (15 parts by weight, produced by NIPPON SODA CO., LTD.) as a curing agent, and rosin (5 parts by weight) were blended together. Then, the obtained conductive particles A (10 parts by weight) were further added thereto. The mixture was stirred with a planetary stirrer at 2000 rpm for five minutes to provide an anisotropic conductive material in the form of an anisotropic conductive paste.

### Example 2

Conductive particles and an anisotropic conductive material were prepared in the same manner as in Example 1, except that the solder layer was formed to have a thickness of 3 μm by electroplating using an electroplating solution containing tin and bismuth.

### Example 3

Conductive particles and an anisotropic conductive material were prepared in the same manner as in Example 1, except that the solder layer was formed to have a thickness of 5 μm by electroplating using an electroplating solution containing tin and bismuth.

### Example 4

Conductive particles and an anisotropic conductive material were prepared in the same manner as in Example 1, except that divinyl benzene resin particles (produced by SEKISUI CHEMICAL CO., LTD., Micropearl SP-230) having an average particle size of 30 μm were used as resin particles.

### Example 5

Conductive particles and an anisotropic conductive material were prepared in the same manner as in Example 2, except that divinyl benzene resin particles (produced by SEKISUI CHEMICAL CO., LTD., Micropearl SP-230) having an average particle size of 30 μm were used as resin particles.

### Example 6

Conductive particles and an anisotropic conductive material were prepared in the same manner as in Example 3, except that divinyl benzene resin particles (produced by SEKISUI CHEMICAL CO., LTD., Micropearl SP-230) having an average particle size of 30 μm were used as resin particles.

### Example 7

Conductive particles and an anisotropic conductive material were prepared in the same manner as in Example 1, except that the solder layer was formed to have a thickness of 7 μm by electroplating using an electroplating solution containing tin and bismuth.

### Example 8

### (1) Preparation of Conductive Particles

Divinyl benzene resin particles (produced by SEKISUI CHEMICAL CO., LTD., Micropearl SP-220) having an average particle size of 20 μm were subjected to electroplating using an electroplating solution containing tin and bismuth so that a solder layer having a thickness of 1 μm was formed on each surface of the resin particles. Thus, conductive particles B were prepared in which a solder layer (tin:bismuth=43:57 (wt %)) having a thickness of 1 μm was formed on each surface of the resin particles.

### (2) Preparation of Anisotropic Conductive Material

Conductive particles and an anisotropic conductive material were prepared in the same manner as in Example 1, except that the conductive particles A were changed to the conductive particles B.

### Example 9

Conductive particles and an anisotropic conductive material were prepared in the same manner as in Example 1, except that the amount of the conductive particles A was changed from 10 parts by weight to 1 part by weight.

### Example 10

Conductive particles and an anisotropic conductive material were prepared in the same manner as in Example 1, except that the amount of the conductive particles A was changed from 10 parts by weight to 30 parts by weight.

### Example 11

Conductive particles and an anisotropic conductive material were prepared in the same manner as in Example 1, except that the amount of the conductive particles A was changed from 10 parts by weight to 80 parts by weight.

### Example 12

Conductive particles and an anisotropic conductive material were prepared in the same manner as in Example 1, except that the amount of the conductive particles A was changed from 10 parts by weight to 150 parts by weight.

### Example 13

Conductive particles and an anisotropic conductive material were prepared in the same manner as in Example 1, except that rosin was not added.

### Example 14

Conductive particles and an anisotropic conductive material were prepared in the same manner as in Example 1, except that divinyl benzene resin particles having an average particle size of 40 μm were used as the resin particles.

### Example 15

Conductive particles and an anisotropic conductive material were prepared in the same manner as in Example 1, except that divinyl benzene resin particles having an average particle size of 10 μm were used as the resin particles.

### Example 16

Conductive particles and an anisotropic conductive material were prepared in the same manner as in Example 1, except that the binder resin was changed from TEPIC-PAS 522 (produced by NISSAN CHEMICAL INDUSTRIES, LTD., specific gravity of 1.2) to EXA-4850-150 (produced by DIC Corporation, specific gravity of 1.2).

### Example 17

Conductive particles and an anisotropic conductive material were prepared in the same manner as in Example 16, except that PM-20L (produced by Tokuyama Corporation, 0.5 parts by weight) was added as fumed silica.

### Example 18

Conductive particles and an anisotropic conductive material were prepared in the same manner as in Example 16, except that PM-20L (produced by Tokuyama Corporation, 2 parts by weight) was added as fumed silica.

### Example 19

Conductive particles and an anisotropic conductive material were prepared in the same manner as in Example 16, except that PM-20L (produced by Tokuyama Corporation, 4 parts by weight) was added as fumed silica.

### Example 20

### (1) Preparation of Conductive Particles

Divinyl benzene resin particles (produced by SEKISUI CHEMICAL CO., LTD., Micropearl SP-220) having an average particle size of 20 μm were subjected to electroless nickel plating so that a base nickel plated layer having a thickness of 0.1 μm was formed on each surface of the resin particles. Next, the resulting resin particles were subjected to electroplating using an electroplating solution containing tin and bismuth so that a solder layer having a thickness of 1 μm was formed. Thus, conductive particles C were prepared in which a solder layer (tin:bismuth=43:57 (wt %)) having a thickness of 1 μm was formed on each surface of the resin particles.

### (2) Preparation of Anisotropic Conductive Material

Conductive particles and an anisotropic conductive material were prepared in the same manner as in Example 1, except that the conductive particles C were used instead of the conductive particles A.

### Comparative Example 1

An anisotropic conductive material were prepared in the same manner as in Example 1, except that solder particles (tin:bismuth=43:57 (wt %), average particle size 15 μm) were used.

(Evaluation)

### (1) Viscosity of Anisotropic Conductive Material

The prepared anisotropic conductive materials were each stored at 25° C. for 72 hours. Then, the respective anisotropic conductive materials were stirred. The viscosity of each anisotropic conductive material was measured in a state where the conductive particles did not settle out.

The viscosity η5 at 25° C. and 5 rpm was measured using an E-type viscometer (produced by TOKI SANGYO CO., LTD., trade name: VISCOMETER TV-22, rotor: φ15 mm, temperature: 25° C.).

Similarly, the viscosity η0.5 at 25° C. and 0.5 rpm was measured. The viscosity ratio (η0.5/η5) was obtained.

### (2) Storage Stability

The prepared anisotropic conductive materials were each stored at 25° C. for 72 hours. Then, settlement of the conductive particles in each anisotropic conductive material was visually checked. The case where the conductive particles did not settle out was evaluated as “0” and the case where the conductive particles settled out was evaluated as “x”. Tables 1 and 2 show the results.

### (3) Preparation of Connection Structure

A FR4 board was prepared in which a gold electrode pattern (L/S=200/200 (μm)) was formed on the top surface. Separately, a polyimide board (flexible board) was prepared in which a gold electrode pattern (L/S=200/200 (μm)) was formed on the under surface. The prepared anisotropic conductive material was stored at 25° C. for 72 hours.

To the top surface of the FR4 board, the anisotropic conductive material having been stored at 25° C. for 72 hours was applied, without stirring, to have a thickness of 50 μm, so that an anisotropic conductive material layer was formed.

On the top surface of the anisotropic conductive material layer, the polyimide board (flexible board) was stacked in such a manner that the electrodes are opposite one another. Then, an autoclaving head was placed on the top surface of a semiconductor chip while the temperature of the head was adjusted so that the anisotropic conductive material layer has a temperature of 200° C. Solder was molten with application of a pressure at 2.0 MPa and the anisotropic conductive material layer was cured at 185° C. In this manner, a connection structure (connection structure produced from an unstirred anisotropic conductive material) was obtained.

Separately, with use of the anisotropic conductive material in which the conductive particles are again dispersed by stirring of the anisotropic conductive material after storage at 25° C. for 72 hours, a connection structure (connection structure produced from a stirred anisotropic conductive material) was obtained in the same way as described above.

### (4) Insulation Property Test Between Electrodes Adjacent to Each Other in the Lateral Direction

The resistance was measured using a tester to determine presence of current leakage between the adjacent electrodes in the obtained connection structures. The case where the resistance was 500 MΩ or smaller was evaluated as “x”. The case where the resistance was larger than 500 MΩ and not larger than 1000 MΩ was evaluated as “Δ”. The case where the resistance was larger than 1000 MΩ was evaluated as “∘”. Tables 1 and 2 show the results.

### (5) Conduction Test Between Upper and Lower Electrodes

The connection resistance between the upper and lower electrodes of each obtained connection structure was measured by the four-terminal method. The average value of two connection resistances was calculated. Here, the connection resistance is obtainable by measuring the voltage at the time when a certain current was applied, based on a relation of “voltage=current×resistance”. The case where the average value was 1.2Ω or smaller was evaluated as “∘”. The case where the average value was larger than 1.2Ω and smaller than 2Ω was evaluated as “Δ”. The case where the average value was larger than 2Ω was evaluated as “x”.

### (6) Impact Resistance Test

A FR4 board was prepared in which a gold electrode pattern (L/S=100/100 (μm)) was formed on the top surface. Separately, a semiconductor chip was prepared in which a gold electrode pattern (L/S=100/100 (μm)) was formed on the under surface. The prepared anisotropic conductive material was stored at 25° C. for 72 hours.

To the top surface of the FR4 board, the anisotropic conductive material having been stored at 25° C. for 72 hours was applied, without stirring, to have a thickness of 50 μm, so that an anisotropic conductive material layer was formed.

On the top surface of the anisotropic conductive material layer, the semiconductor chip was stacked in such a manner that the electrodes are opposite one another. Then, an autoclaving head was placed on the top surface of the semiconductor chip while the temperature of the head was adjusted so that the anisotropic conductive material layer has a temperature of 200° C. Solder was molten with application of a pressure at 2.0 MPa and the anisotropic conductive material layer was cured at 185° C. In this manner, a connection structure (connection structure produced from an unstirred anisotropic conductive material) was obtained.

Separately, with use of the anisotropic conductive material in which the conductive particles are again dispersed by stirring of the anisotropic conductive material after storage at 25° C. for 72 hours, a connection structure (connection structure produced from a stirred anisotropic conductive material) was obtained in the same way as described above.

The boards were dropped from a height of 70 cm and conduction at each solder-jointed part was checked. In this manner, the impact resistance was evaluated. The case where the rate of resistance increase from the initial resistance value was not more than 30% was evaluated as “∘”. The case where the rate of resistance increase from the initial resistance value was more than 30% and not more than 50% was evaluated as “Δ”. The case where the rate of resistance increase from the initial resistance value was more than 50% is evaluated as “x”. Tables 1 and 2 show the results.

TABLE 1

| | | Average | | | Specific | | | | | | |
|---|---|---|---|---|---|---|---|---|---|---|---|
| | | particle | Thickness | Thickness | gravity | | | | | | |
| | | size (μm) | (μm) of | (μm) of | of | | | | | | |
| | | of resin | copper | solder | conductive | | | | | | |
| | | particles | layer | layer | particles | Example 1 | Example 2 | Example 3 | Example 4 | Example 5 | Example 6 |
| Com- | Conductive | 20 | 1 | 1 | 4.51 | 10 | | | | | |
| position | particles each | 20 | 1 | 3 | 6.07 | | 10 | | | | |
| (parts | containing a resin | 20 | 1 | 5 | 6.95 | | | 10 | | | |
| by | particle and a | 30 | 1 | 1 | 3.67 | | | | 10 | | |
| weight) | conductive layer | 30 | 1 | 3 | 5.1 | | | | | 10 | |
| | (multilayer) | 30 | 1 | 5 | 6.04 | | | | | | 10 |
| | | 20 | 1 | 7 | 7.48 | | | | | | |
| | | 40 | 1 | 1 | 3.17 | | | | | | |
| | | 10 | 1 | 1 | 6.14 | | | | | | |
| | | 20 | 0 | 1 | 3.22 | | | | | | |
| | Conductive particles | 20 | — | 1 | 3.08 | | | | | | |
| | each containing a | | | | | | | | | | |
| | resin particle and a | | | | | | | | | | |
| | solder layer | | | | | | | | | | |
| | (monolayer) | | | | | | | | | | |
| | Solder particles | — | — | — | 8.75 | | | | | | |
| | (15 μm) | | | | | | | | | | |
| | Binder resin | | TEPIC-PAS B22 | | | 100 | 100 | 100 | 100 | 100 | 100 |
| | (specific gravity 1.2) | | EXA-4850-150 | | | | | | | | |
| | Curing agent | | TEP-2E4MZ | | | 15 | 15 | 15 | 15 | 15 | 15 |
| | Fumed silica | | PM-20L | | | | | | | | |
| | Rosin | | | | | 5 | 5 | 5 | 5 | 5 | 5 |
| | Amount of conductive particles in 100 wt % | | | | | 7.7 | 7.7 | 7.7 | 7.7 | 7.7 | 7.7 |
| | of anisotropic conductive material (wt %) | | | | | | | | | | |
| Evalua- | (1) Viscosity η5 at 25° C. and 5 rpm | | | | | 2 | 2 | 2 | 2 | 2 | 2 |
| tion | (1) Viscosity η0.5 at 25° C. and 0.5 rpm | | | | | 2 | 2 | 2 | 2 | 2 | 2 |
| | (1) Viscosity ratio (Viscosity η0.5/Viscosity η5) | | | | | 1.00 | 1.00 | 1.00 | 1.00 | 1.00 | 1.00 |
| | (2) Storage stability | | | | | ◯ | ◯ | ◯ | ◯ | ◯ | ◯ |
| | (4) Insulation property test | | Unstirred anisotropic | | | ◯ | ◯ | ◯ | ◯ | ◯ | ◯ |
| | between adjacent | | conductive material used | | | | | | | | |
| | electrodes in | | Stirred anisotropic | | | ◯ | ◯ | ◯ | ◯ | ◯ | ◯ |
| | connection structure | | conductive material used | | | | | | | | |
| | (5) Conduction test | | Unstirred anisotropic | | | ◯ | ◯ | ◯ | ◯ | ◯ | ◯ |
| | between upper and lower | | conductive material used | | | | | | | | |
| | electrodes in | | Stirred anisotropic | | | ◯ | ◯ | ◯ | ◯ | ◯ | ◯ |
| | connection structure | | conductive material used | | | | | | | | |
| | (6) Impact resistance test | | Unstirred anisotropic | | | ◯ | ◯ | ◯ | ◯ | ◯ | ◯ |
| | of connection structure | | conductive material used | | | | | | | | |
| | | | Stirred anisotropic | | | ◯ | ◯ | ◯ | ◯ | ◯ | ◯ |
| | | | conductive material used | | | | | | | | |
| | | Average | | | Specific | | | | | | |
| | | particle | Thickness | Thickness | gravity | | | | | | |
| | | size (μm) | (μm) of | (μm) of | of | | | | | | |
| | | of resin | copper | solder | conductive | | | | Example | Example | Example |
| | | particles | layer | layer | particles | Example 7 | Example 8 | Example 9 | 10 | 11 | 12 |
| Com- | Conductive | 20 | 1 | 1 | 4.51 | | | 1 | 30 | 80 | 150 |
| position | particles each | 20 | 1 | 3 | 6.07 | | | | | | |
| (parts | containing a resin | 20 | 1 | 5 | 6.95 | | | | | | |
| by | particle and a | 30 | 1 | 1 | 3.67 | | | | | | |
| weight) | conductive layer | 30 | 1 | 3 | 5.1 | | | | | | |
| | (multilayer) | 30 | 1 | 5 | 6.04 | | | | | | |
| | | 20 | 1 | 7 | 7.48 | 10 | | | | | |
| | | 40 | 1 | 1 | 3.17 | | | | | | |
| | | 10 | 1 | 1 | 6.14 | | | | | | |
| | | 20 | 0 | 1 | 3.22 | | | | | | |
| | Conductive particles | 20 | — | 1 | 3.08 | | 10 | | | | |
| | each containing a | | | | | | | | | | |
| | resin particle and a | | | | | | | | | | |
| | solder layer | | | | | | | | | | |
| | (monolayer) | | | | | | | | | | |
| | Solder particles | — | — | — | 8.75 | | | | | | |
| | (15 μm) | | | | | | | | | | |

| | Binder resin | TEPIC-PAS B22 | 100 | 100 | 100 | 100 | 100 | 100 |
|---|---|---|---|---|---|---|---|---|
| | (specific gravity 1.2) | EXA-4850-150 | | | | | | |
| | Curing agent | TEP-2E4MZ | 15 | 15 | 15 | 15 | 15 | 15 |
| | Fumed silica | PM-20L | | | | | | |
| | Rosin | | 5 | 5 | 5 | 5 | 5 | 5 |
| | Amount of conductive particles in 100 wt % | | 7.7 | 7.7 | 0.8 | 20 | 40 | 55.6 |
| | of anisotropic conductive material (wt %) | | | | | | | |
| Evalua- | (1) Viscosity η5 at 25° C. and 5 rpm | | 2 | 2 | 2 | 3 | 5 | 10 |
| tion | (1) Viscosity η0.5 at 25° C. and 0.5 rpm | | 2 | 2 | 2 | 3.3 | 5.6 | 11.5 |
| | (1) Viscosity ratio (Viscosity η0.5/Viscosity η5) | | 1.00 | 1.00 | 1.00 | 1.10 | 1.12 | 1.15 |
| | (2) Storage stability | | X | ◯ | ◯ | ◯ | ◯ | ◯ |
| | (4) Insulation property test | Unstirred anisotropic | X | ◯ | ◯ | ◯ | ◯ | Δ |
| | between adjacent | conductive material used | | | | | | |
| | electrodes in | Stirred anisotropic | ◯ | ◯ | ◯ | ◯ | ◯ | Δ |
| | connection structure | conductive material used | | | | | | |
| | (5) Conduction test | Unstirred anisotropic | X | ◯ | Δ | ◯ | ◯ | ◯ |
| | between upper and lower | conductive material used | | | | | | |
| | electrodes in | Stirred anisotropic | ◯ | ◯ | Δ | ◯ | ◯ | ◯ |
| | connection structure | conductive material used | | | | | | |
| | (6) Impact resistance test | Unstirred anisotropic | X | Δ | ◯ | ◯ | ◯ | ◯ |
| | of connection structure | conductive material used | | | | | | |
| | | Stirred anisotropic | ◯ | Δ | ◯ | ◯ | ◯ | ◯ |
| | | conductive material used | | | | | | |

TABLE 2

| | | Average | | | | | | | | |
|---|---|---|---|---|---|---|---|---|---|---|
| | | particle | | | | | | | | |
| | | size (μm) | Thickness | Thickness | Specific gravity | | | | | |
| | | of resin | (μm) of | (μm) of | of conductive | Example | Example | Example | Example | Example |
| | | particles | copper layer | solder layer | particles | 13 | 14 | 15 | 16 | 17 |
| Com- | Conductive | 20 | 1 | 1 | 4.51 | 10 | | | 10 | 10 |
| position | particles each | 20 | 1 | 3 | 6.07 | | | | | |
| (parts | containing a resin | 20 | 1 | 5 | 6.95 | | | | | |
| by | particle and a | 30 | 1 | 1 | 3.67 | | | | | |
| weight) | conductive layer | 30 | 1 | 3 | 5.1 | | | | | |
| | (multilayer) | 30 | 1 | 5 | 6.04 | | | | | |
| | | 20 | 1 | 7 | 7.48 | | | | | |
| | | 40 | 1 | 1 | 3.17 | | 10 | | | |
| | | 10 | 1 | 1 | 6.14 | | | 10 | | |
| | | 20 | 0 | 1 | 3.22 | | | | | |
| | Conductive particles | 20 | — | 1 | 3.08 | | | | | |
| | each containing a | | | | | | | | | |
| | resin particle and a | | | | | | | | | |
| | solder layer | | | | | | | | | |
| | (monolayer) | | | | | | | | | |
| | Solder particles | — | — | — | 8.75 | | | | | |
| | (15 μm) | | | | | | | | | |

| | Binder resin | TEPIC-PAS B22 | 100 | 100 | 100 | | |
|---|---|---|---|---|---|---|---|
| | (specific gravity 1.2) | EXA-4850-150 | | | | 100 | 100 |
| | Curing agent | TEP-2E4MZ | 15 | 15 | 15 | 15 | 15 |
| | Fumed silica | PM-20L | | | | 0 | 0.5 |
| | Rosin | | | 5 | 5 | 5 | 5 |
| | Amount of conductive particles in 100 wt % | | 8 | 7.7 | 7.7 | 7.7 | 7.7 |
| | of anisotropic conductive material (wt %) | | | | | | |
| Evalua- | (1) Viscosity η5 at 25° C. and 5 rpm | | 2 | 2 | 2 | 20 | 25 |
| tion | (1) Viscosity η0.5 at 25° C. and 0.5 rpm | | 2 | 2 | 2 | 20 | 30 |
| | (1) Viscosity ratio (Viscosity η0.5/Viscosity η5) | | 1.00 | 1.00 | 1.00 | 1.00 | 1.20 |
| | (2) Storage stability | | ◯ | ◯ | ◯ | ◯ | ◯ |
| | (4) Insulation property | Unstirred anisotropic conductive material used | ◯ | ◯ | ◯ | ◯ | ◯ |
| | test between adjacent | Stirred anisotropic conductive material used | ◯ | ◯ | ◯ | ◯ | ◯ |
| | electrodes in | | | | | | |
| | connection structure | | | | | | |
| | (5) Conduction test | Unstirred anisotropic conductive material used | Δ | ◯ | ◯ | ◯ | ◯ |
| | between upper and lower | Stirred anisotropic conductive material used | Δ | ◯ | ◯ | ◯ | ◯ |
| | electrodes in | | | | | | |
| | connection structure | | | | | | |
| | (6) Impact resistance test | Unstirred anisotropic conductive material used | ◯ | ◯ | ◯ | ◯ | ◯ |
| | of connection structure | Stirred anisotropic conductive material used | ◯ | ◯ | ◯ | ◯ | ◯ |

| | | Average | | | | | | | |
|---|---|---|---|---|---|---|---|---|---|
| | | particle | | | | | | | |
| | | size (μm) | Thickness | Thickness | Specific gravity | | | | |
| | | of resin | (μm) of | (μm) of | of conductive | Example | Example | Example | Comparative |
| | | particles | copper layer | solder layer | particles | 18 | 19 | 20 | Example 1 |
| Com- | Conductive | 20 | 1 | 1 | 4.51 | 10 | 10 | | |
| position | particles each | 20 | 1 | 3 | 6.07 | | | | |
| (parts | containing a resin | 20 | 1 | 5 | 6.95 | | | | |
| by | particle and a | 30 | 1 | 1 | 3.67 | | | | |
| weight) | conductive layer | 30 | 1 | 3 | 5.1 | | | | |
| | (multilayer) | 30 | 1 | 5 | 6.04 | | | | |
| | | 20 | 1 | 7 | 7.48 | | | | |
| | | 40 | 1 | 1 | 3.17 | | | | |
| | | 10 | 1 | 1 | 6.14 | | | | |
| | | 20 | 0 | 1 | 3.22 | | | 10 | |
| | Conductive particles | 20 | — | 1 | 3.08 | | | | |
| | each containing a | | | | | | | | |
| | resin particle and a | | | | | | | | |
| | solder layer | | | | | | | | |
| | (monolayer) | | | | | | | | |
| | Solder particles | — | — | — | 8.75 | | | | 10 |
| | (15 μm) | | | | | | | | |

| | Binder resin | TEPIC-PAS B22 | | | 100 | 100 |
|---|---|---|---|---|---|---|
| | (specific gravity 1.2) | EXA-4850-150 | 100 | 100 | | |
| | Curing agent | TEP-2E4MZ | 15 | 15 | 15 | 15 |
| | Fumed silica | PM-20L | 2 | 4 | | |
| | Rosin | | 5 | 5 | 5 | 5 |
| | Amount of conductive particles in 100 wt % | | 7.6 | 7.5 | 7.7 | 7.7 |
| | of anisotropic conductive material (wt %) | | | | | |
| Evalua- | (1) Viscosity η5 at 25° C. and 5 rpm | | 35 | 45 | 2 | — |
| tion | (1) Viscosity η0.5 at 25° C. and 0.5 rpm | | 70 | 130 | 2 | — |
| | (1) Viscosity ratio (Viscosity η0.5/Viscosity η5) | | 2.00 | 2.89 | 1.00 | — |
| | (2) Storage stability | | ◯ | ◯ | ◯ | X |
| | (4) Insulation property | Unstirred anisotropic conductive material used | ◯ | ◯ | ◯ | X |
| | test between adjacent | Stirred anisotropic conductive material used | ◯ | ◯ | ◯ | ◯ |
| | electrodes in | | | | | |
| | connection structure | | | | | |
| | (5) Conduction test | Unstirred anisotropic conductive material used | ◯ | ◯ | ◯ | X |
| | between upper and lower | Stirred anisotropic conductive material used | ◯ | ◯ | ◯ | ◯ |
| | electrodes in | | | | | |
| | connection structure | | | | | |
| | (6) Impact resistance test | Unstirred anisotropic conductive material used | ◯ | ◯ | Δ | X |
| | of connection structure | Stirred anisotropic conductive material used | ◯ | ◯ | Δ | X |

As shown in Tables 1 and 2, in the connection structures comprising the anisotropic conductive materials in which the conductive particles were again dispersed in Examples 1 to 20, no leakage was found between the electrodes adjacent to each other in the lateral direction, and the upper and lower electrodes are sufficiently connected to each other. In addition, in the anisotropic conductive materials of Examples 1 to 20, the conductive particles hardly settle out even in storage for a long time, so that the anisotropic conductive material is excellent in the storage stability. In the connection structures of Examples 1 to 20 which are formed of the anisotropic conductive materials containing conductive particles each having a resin particle, the conductive particles each have a highly-flexible resin particle in its core part. In such connection structures, electrodes coming in contact with the conductive particles are less likely to be damaged and excellent in the impact resistance, compared to the connection structure of Comparative Example 1 which is formed of the anisotropic conductive material containing solder particles.

### REFERENCE SIGNS LIST

1. Conductive particle
1a. Surface
2. Resin particle
2a. Surface
3. Conductive layer
4. First conductive layer
4a. Surface
5. Solder layer
5a. Molten solder layer part
11. Conductive particle
12. Solder layer
21. Connection structure
22. First connection target member
22a. Top surface
22b. First electrode
23. Second connection target member
23a. Under surface
23b. Second electrode
24. Connection part

1. An anisotropic conductive material comprising:
conductive particles each including a resin particle and a conductive layer coating the surface of the resin particle; and
a binder resin;
wherein at least an exterior surface layer of the conductive layer is a solder layer.

2. The anisotropic conductive material according to claim 1,
wherein a difference in specific gravity is not More than 6.0 between the conductive particles and the binder resin.

3. The anisotropic conductive material according to claim 1,
wherein the conductive particles have a specific gravity of 1.0 to 7.0 and the binder resin has a specific gravity of 0.8 to 2.0.

4. The anisotropic conductive material according to claim 1,
wherein the conductive particles have an average particle size of 1 to 100 μm.

5. The anisotropic conductive material according to claim 1, further comprising a flux.

6. The anisotropic conductive material according to claim 1,
wherein the conductive particles each have a first conductive layer as a part of the conductive layer, in addition to the solder layer, between the resin particle and the solder layer.

7. The anisotropic conductive material according to claim 6,
wherein the first conductive layer is a copper layer.

8. The anisotropic conductive material according to claim 1,
wherein an amount of the conductive particles is 1 to 50 wt % in 100 wt % of the anisotropic conductive material.

9. The anisotropic conductive material according to claim 1,
which is in a liquid form with a viscosity of 1 to 300 Pa·s at 25° C. and 5 rpm.

10. The anisotropic conductive material according to claim 1,
which is in a liquid form with a viscosity ratio of the viscosity at 25° C. and 0.5 rpm to the viscosity at 25° C. and 5 rpm of 1.1 to 3.0.

11. A connection structure comprising:
a first connection target member;
a second connection target member; and
a connection part connecting the first connection target member and the second connection target member,
wherein the connection part is formed of the anisotropic conductive material according to claim 1.

12. The connection structure according to claim 11,
wherein the first connection target member has a plurality of first electrodes and the second connection target member has a plurality of second electrodes, and
the plurality of first electrodes and the plurality of second electrodes are electrically connected to each other via, the conductive particles included in the anisotropic conductive material.

13. The connection structure according to claim 12,
wherein the plurality of first electrodes adjacent to each other are positioned at an interval of not more than 200 μm and the plurality of second electrodes adjacent to each other are positioned at an interval of not more than 200 μm, and
the conductive particles have an average particle size of not more than ¼ of the interval between the plurality of first electrodes adjacent to each other and not more than ¼ of the interval between the plurality of second electrodes adjacent to each other.
